(19) United States
(12) Patent Application Publication
(10) Pub. No.: US 2025/0070780 A1
(43) Pub. Date: Feb. 27, 2025

(54) CIRCUITS AND METHODS TO HARVEST ENERGY FROM TRANSIENT ON-CHIP DATA

(71) Applicant: Metis Microsystems, LLC, Newtown, CT (US)

(72) Inventor: Azeez BHAVNAGARWALA, Newtown, CT (US)

(73) Assignee: Metis Microsystems, LLC, Newtown, CT (US)

(21) Appl. No.: 18/624,830

(22) Filed: Apr. 2, 2024

Related U.S. Application Data
(63) Continuation of application No. 17/498,220, filed on Oct. 11, 2021, now Pat. No. 11,984,888.
(60) Provisional application No. 63/139,744, filed on Jan. 20, 2021.
(60) Provisional application No. 63/090,169, filed on Oct. 9, 2020.

(51) Int. Cl. H03K 19/00; G01R 19/165; H03K 19/094; H03K 19/096; H03K 19/20

(52) U.S. Cl. CPC H03K 19/0019; G01R 19/16552; H03K 19/0013; H03K 19/094; H03K 19/0963; H03K 19/20

(57) ABSTRACT

Circuits and methods that harvest electrostatic energy from transient on-chip data are described in the Application. In one aspect, a method inverter circuit harvests electrostatic charge held at its output node at an electric potential comparable to the power supply voltage rail to a common grid/node as the output makes a 0→1 logic transition. This charge harvested at a common gride/node can be used by circuits (described in applications 63/090,169, 63/139,744) to drive 0→1 logic transition at their output nodes at lower energy drain from the on-chip power grid than a conventional CMOS inverter would with similar performance, slew rates at inverter input and output and with similar output driving transistor geometries.

### CROSS-REFERENCE TO RELATED APPLICATIONS

This application is a continuation of U.S. patent application Ser. No. 17/498,220, filed Oct. 11, 2021, which claims priority to and benefit of U.S. Provisional Application No. 63/090,169 filed on Oct. 9, 2020 and U.S. Provisional Application No. 63/139,744 filed on Jan. 20, 2021, the entire disclosures of each of which are incorporated herein by reference in its entirety.

### FIELD OF INVENTION

The present invention relates to harvest of electrostatic energy from transient on-chip data to improve the energy efficiency of digital CMOS circuit operation.

### BACKGROUND OF INVENTION

In recent years, deep neural networks (DNNs) have become the solution for many AI applications including computer vision, speech recognition and robotics implementing machine learning methods. While these neural networks deliver sufficient accuracy—it comes at the cost of high computational complexity with associated power drain limiting deep learning from being deployed on mobile devices with limited energy budgets. Smart phones for example, cannot run object classification with AlexNet in real-time for more than an hour. Network issues of latency, bandwidth and availability could require battery/ambient powered IoT devices on the edge to not only sense and act without communicating to the cloud but also to take on more computationally intense tasks of learning or training a neural network. Neural networks for a myriad of IoT devices can easily result in model sizes that are enormous—becoming computationally burdensome to. their energy resources, demanding energy budgets that exceed provisions from batteries and conventional energy harvesting methods. Even where power is abundantly available as in a data center supporting AI workloads, where GPU accelerators consume as much as 400 W, the cost of electricity and the performance limits imposed by heat removal efficiency can be improved by lowering the switching (or Dynamic) energy consumption of digital CMOS circuits

### PRIOR ART

In many applications requiring high speed CMOS circuit operation, precharged dynamic circuit techniques are preferred. These circuits are typically operated by pre-charging output nodes to the supply voltage during a pre-charge phase every clock cycle and conditionally discharging some of them, depending on the inputs during the evaluation phase. These techniques are energy inefficient since all of the charge discarded to the reference ground potential during evaluate must be resupplied during precharge phase of the next clock cycle. High peak currents can also cause large di/dt noise causing voltage bumps in power rails with associated risks to signal integrity and reliability in high performance CMOS components.

Dynamic logic circuits that recycle some of the charge were proposed to improve the energy efficiency of circuit operation. These circuit techniques precharge complementary outputs to half V_{DD} by charge sharing from the previous evaluation state, enabling a maximum of a 50% reduction in energy. Such schemes are relevant only when complementary signal pairs are used in implementing complex logic functions. Also, much of the charge recycle benefits are lost with performance degraded as well due to (i) high overheads in device count (ii) requirement of using complementary inputs and as many as 2-3 clock and enable inputs to each logic gate with their associated additional routing, performance and power overheads (iii) use of cross-coupled inverters as output drivers which increase the uncertainty of gate metrics in the presence of parameter variations and the offsets they develop, and (iv) with only a half-VDD gate-source voltage precharged to output and input nodes of output drivers for charge recycle operation, gate overdrive is degraded during evaluation phase. In one comparison with static CMOS implementing full adders, the power-delay product of a full adder increases total energy nearly 10% over static CMOS. Moreover, neural network energy consumption is dominated by movement of data across the memory hierarchy and the chip and not by dissipation from computation.

On-chip small voltage swing signaling schemes have attempted charge recycling by stacking components (such as logic and. clocking circuits) with predictable data switching activities in two adjacent voltage domains using simple push-pull regulators to balance current between the two domains to maintain the voltage at their interface. This approach could deliver a maximum of a quadratic reduction in power. Inefficiency introduced by voltage regulation is eliminated if the current between domains is matched. An approach to stack voltage domains without requiring regulators between them has been reported using a balanced charge recycling bus where differing data activity between two links is compensated by swapping data between them periodically so that switching activity along the bus is exactly matched. These schemes however, are difficult to implement and also require circuits in the domains to be powered by reduced operating voltages.

Charge recycling techniques have been reported where the flow of electric charge from the supply rail (V_{DD}) to Ground is traced through more than one circuit/use through multiple voltage domains. However, there is no energy advantage from recycling the charge through multiple voltage domains since it costs as much in energy to raise charge to the highest voltage domain as it does to do so cumulatively in each of the stacked domains operating independently. The energy advantage of stacking voltage domains is only in removing she inefficiencies of on-chip voltage regulation from V_{DD} to much lower voltages that these domains would be powered with to benefit from quadratic reductions in their switching power. If the current between domains is not matched, the energy overhead consumed by regulators attempting to maintain domain interface at a fixed voltage, could diminish the quadratic energy improvements from operating each domain at reduced voltages.

Non-resonant approaches to returning/recycling stored energy on load capacitance include use of an inductor to discharge load capacitor of a clock network to the power grid instead of it being discharged to ground. However, overheads of inductors, decoupling capacitors, integration with clock gating (and its accompanying overheads), and limited application to large clock load capacitances (as seen in a clock mesh) are challenges seen with this approach making it impractical and difficult implement.

Smaller voltage transitions for each logic operation using ‘recycled charge’ also come with the disadvantages of smaller margins and lower performance. In multiple instances, these make implementations impractical. For e.g., in, a smaller (than V_{DD}) voltage is applied across a BL pair during an SRAM Write operation to enable lower energy dissipation per Write operation. By sharing/recycling charge across a set of BL pairs, Writes are attempted with smaller voltage swings on the BL (instead of full rail-rail BL swings during a conventional SRAM Write). For small geometry devices it becomes harder to write to the bitcell even with the full supply voltage across a bit line pair—due to increasing electrical variability seen in small-geometry bitcell transistors. Circuit overheads introduced by full CMOS transmission gates to move charge between columns comes at a significant cost in area, control and performance.

Adiabatic switching in reversible logic circuits moves charge from the power supply to a load capacitance using slow constant current charging without energy dissipation. It enables the recycling of energy to reduce the total energy drawn from the power supply by reversing the current source using non-standard AC or pulsed power supplies with time varying voltage or current. In sharp contrast to conventional CMOS circuit operation, charge and energy are not discarded after being used, only once—with pulsed/sinusoidal power supplies designed to be able to retrieve the energy fed back to it. The problem areas limiting realization of practical low-power operation of CMOS chips using adiabatic or reversible logic techniques: (1) the energy-efficient design of the combined power supply and clock generator (2) logical overhead needed to support reversible logic functions and (3) the alternative of scaling operating voltages with feature size and improving performance—that comes with conceptual simplicity and high payback of lower power dissipation, has been preferred by industry.

### SUMMARY OF INVENTION

Conventional CMOS operation as illustrated by an inverter driving a capacitive load C and which draws energy equal to CV_{DD}² from the power supply rail at voltage V_{DD} during a 0→1 transition at its output, of which energy equal to (½) CV_{DD}² is stored at the output. A 1→0 transition at the output discharges all of this stored energy to the reference ground potential of the inverter at voltage Vss=0V.

In the proposed invention, an inverter driving the same capacitive load C as the above conventional CMOS inverter, draws energy equal to CV_{DD}²—as a conventional CMOS inverter would, but a 1→0 transition at its output node harvests a fraction α of the charge held at the output to a common grid/node raising its electric potential (where α is a positive fraction<1). Typical values of α are 0.25-0.4

### BRIEF DESCRIPTION OF DRAWINGS

FIG. 1 is a schematic illustrating conventional CMOS circuit schematic of an inverter and its operation in response to 1→0 and 0→1 input transitions

FIG. 2 is a circuit simulation of the conventional CMOS inverter circuit that shows voltage waveforms at the input and at the output terminals of the inverter in response to 1→0 and 0→1 input transitions. The Figure also shows the current waveform that illustrates the current flow dependence on time for the 0→1 transition at the output and the 1→0 transition at the output

FIG. 3 is a schematic illustrating the proposed circuit of an inverter that harvests charge from its output at VDD to a common grid/node capacitance when the output makes a 1→0 logic transition moving 0.4×-0.25× of the charge held at its output at VDD to the harvest grid/node V2.

FIG. 4 is a circuit simulation of the proposed inverter circuit that harvests charge during a 1→0 logic transition at its output—showing voltage waveforms at the input and output terminals (that are practically identical to those observed in a conventional CMOS inverter (FIG. 2)) and current waveforms corresponding to current drawn from the power rail at voltage of VDD and current to the common grid/node V2 at voltage VDD/2

### DETAILED DESCRIPTION OF PREFERRED EMBODIMENTS

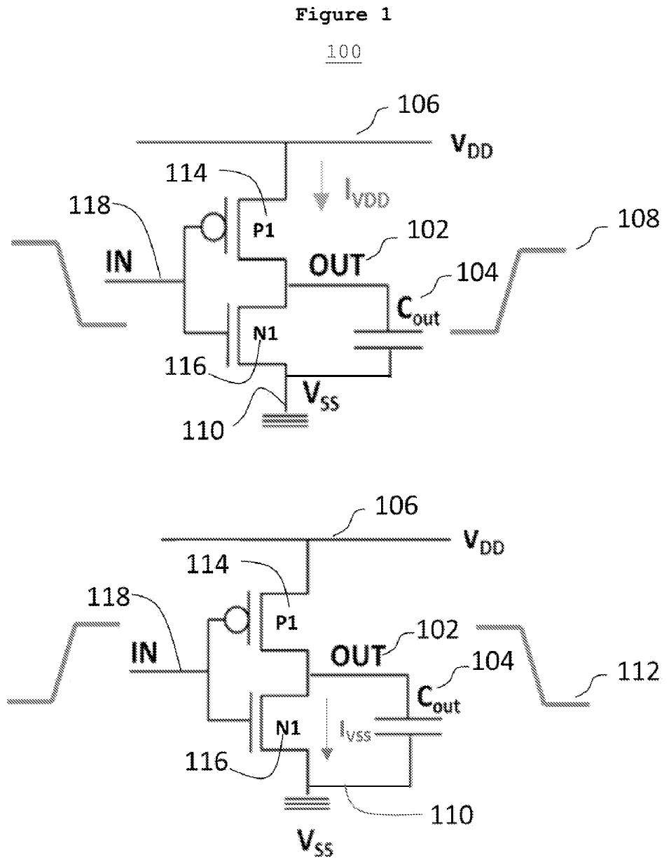

FIG. 1 is a schematic illustrating operation of a conventional CMOS inverter 100 driving output node OUT 102 with a capacitive load Cₒᵤₜ 104. The power rail 106 at electric potential V_{DD} provides total energy equal to Cₒᵤₜ 104 (derived in equation (1) below) during a 0→1 transition 108 at the output node OUT 102, storing energy of (½)CₒᵤₜV_{DD}² on the capacitor 104 at the output 102 modeled by equation (2) below. A 1→0 112 transition at the output 102 discharges from Cₒᵤₜ104 all of this stored energy on the capacitor Cₒᵤₜ 104 at the output 102 to the reference ground node 110 at electric potential Vss=0V

Energy Drawn from VDD Supply (During 0→1 Transition at Output)

$$\int {I}_{V D D} ( t ) {V}_{D D} d t = {\int }_{V S S}^{V D D} {C}_{out} {V}_{D D} d {V}_{out} = {C}_{out} V \begin{matrix}2 \\ DD\end{matrix} \qquad ( 1 )$$

### Energy Stored at Output

$$\int {I}_{V D D} ( t ) {V}_{out} ( t ) d t = {\int }_{V S S}^{V D D} {C}_{out} {V}_{out} d {V}_{out} = 1 / 2 {C}_{out} V \begin{matrix}2 \\ DD\end{matrix} \qquad ( 2 )$$

Energy Discharged from Output (During 0→1 Transition at Output)

$$\int {I}_{V S S} ( t ) {V}_{out} ( t ) dt = {\int }_{V D D}^{V S S} {C}_{out} {V}_{out} d {V}_{out} = 1 / 2 {C}_{out} V \begin{matrix}2 \\ DD\end{matrix} \qquad ( 3 )$$

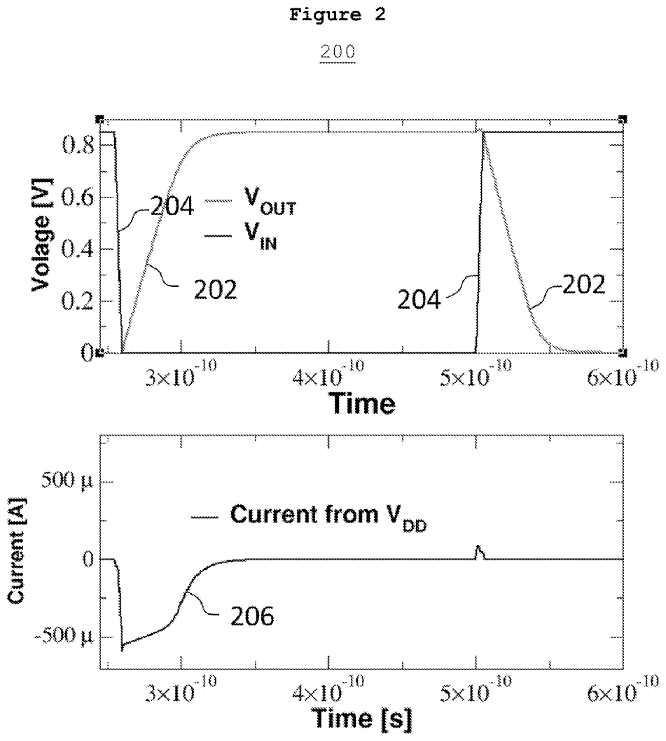

FIG. 2 200 is an illustration of the time dependent voltage waveforms of the output node OUT (102 in FIG. 1 100) shown as the waveform V_{OUT} 202 in FIG. 2. The voltage waveform driving the input of the inverter 118 in FIG. 1, is shown in FIG. 2 as V_{IN} 204

The waveform of current flow 206 into the inverter from the power rail at voltage V_{DD} (106 in FIG. 1) is shown along the same x-axis of time (as used to plot voltage waveforms) in FIG. 2. The absolute value of the integral of the current waveform 206 over time in FIG. 2 200 equals the total charge Q drained from the power rail (106 in FIG. 1) to drive the output node 102 from 0→1. The energy consumed from the power rail 106 to accomplish this logic transition at the output node 102 equals [Q●V_{DD}]CₒᵤₜV_{DD}² modeled in equation (1) above.

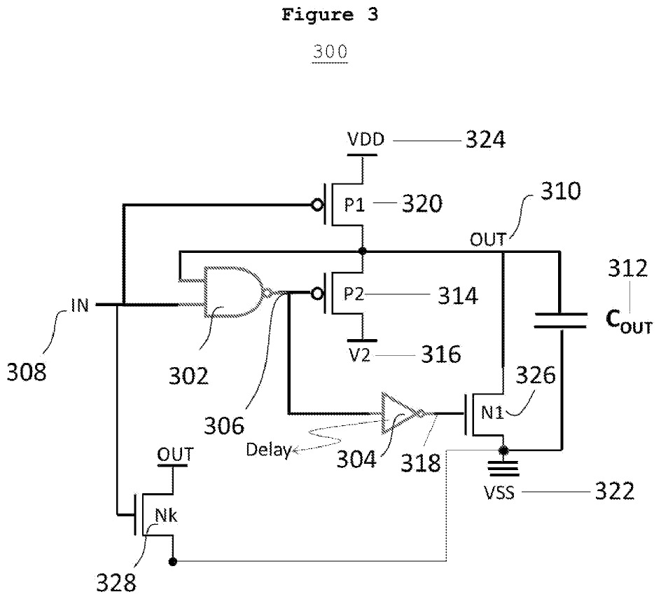

In FIG. 3 the proposed circuit schematic 300 functioning as an inverter shows a 2-input NAND 302 and a delay element 304 that also inverts its input. The 2-input NAND 302 and a delay element 304 have devices with much smaller widths (˜⅕ of driver transistors) than the other transistors (326, 314, 320).

The NAND gate 302 in this schematic generates an active low pulse at its output node 306 whose leading edge is triggered by a 0→1 transition at the input 308 and whose trailing edge is triggered by a 140 transition at the output node 310 loaded with a total capacitance C_{OUT} 312.

The leading edge of this active low pulse turns on PFET P2 314 which drives charge from the output node at logic ‘1’ and voltage VDD to be harvested on the common grid/node V2 316 (typically at a voltage between VSS and VDD and preferably at a voltage comparable to or lower than the logic threshold of the NAND gate 302).

The leading edge of the active low pulse at the output of the NAND gate 306, when delayed and inverted to drive the gate input 318 of NFET N1 326, turns on NFET N1 326 to begin discharging the output 310 to VSS—as the output voltage at node OUT 310 approaches V2. Note that a design requirement on the logic threshold voltage of the NAND gate 302 is that it is higher than the typical voltage node V2 would be raised to with harvested charge or during a dynamic equilibrium when rate of charge transfer to and from the common grid/node are balanced. Thus, node OUT 310 when being discharged to V2 through PFET P2 314, can trip the NAND 302 to produce the trailing low→high transition of the active low pulse at output of the NAND gate 306 to turn-off P2 314.

The NAND 302 would also trip when the N channel FET N1 326 begins conducting after the delayed and inverted leading edge of the active low pulse output from the NAND is inverted by the delay element 304 whose output turns on N1 326.

The output continues being discharged toward VSS—the reference ground terminal 322 as N1 326 is turned on. The trailing edge of the active high pulse driving the gate input terminal of the N channel FET, N1 326 turns this NFET, N1 326 off. A small geometry keeper HVT NFET 328 holds the output to VSS. Its gate input is driven by the inverter input 308 with its source terminal connected to the reference ground voltage rail 322 at voltage VSS=0V and. its drain terminal connected. to OUT 310.

The trailing edge of the active low pulse at the output of the NAND 306 is triggered by the transition at the output node from VDD toward V2 since the logic threshold of the NAND 302 is higher than the voltage at which node V2 316 is typically charged to with harvested charge. The trailing edge is triggered by this feedback from OUT 310 to the input of the NAND 306.

The proposed circuit (1) maintains rail-rail operation (2) drives practically the same waveforms at its output as a conventional inverter and (3) while harvesting about 25%-40% of the total charge it discharges from its output 310—to the harvest grid node V2 316, instead of discharging all of that charge to the reference ground supply rail 322. The primary overhead in area is consumed by the PFET P2 in FIG. 3. The gates in FIG. 3 are small and can be replaced by equivalent standard cells. Transistors N1 326, P1 320in FIG. 3 are identical to the transistors 116 and 114 in the schematic of the inverter in FIG. 1 100.

The NAND gate 302 and the delay element 304 can be optimized to maximize the energy harvested, at the grid/node from the output node of the inverter—according to what voltage the harvested charge is typically held at when using the proposed inverter. The closer the voltage of the harvested charge at V2 316 is to VDD, the higher the optimal logic threshold voltage of the NAND gate 302 should be (to avoid reverse flow of current from harvest grid/node to output node of inverter) and the shorter the delay value of the delay element 304 needs to be to minimize the delay overheads to accomplish the same 1→0 transition at the output of the inverter. This optimization is especially useful when operating at low, near threshold voltages

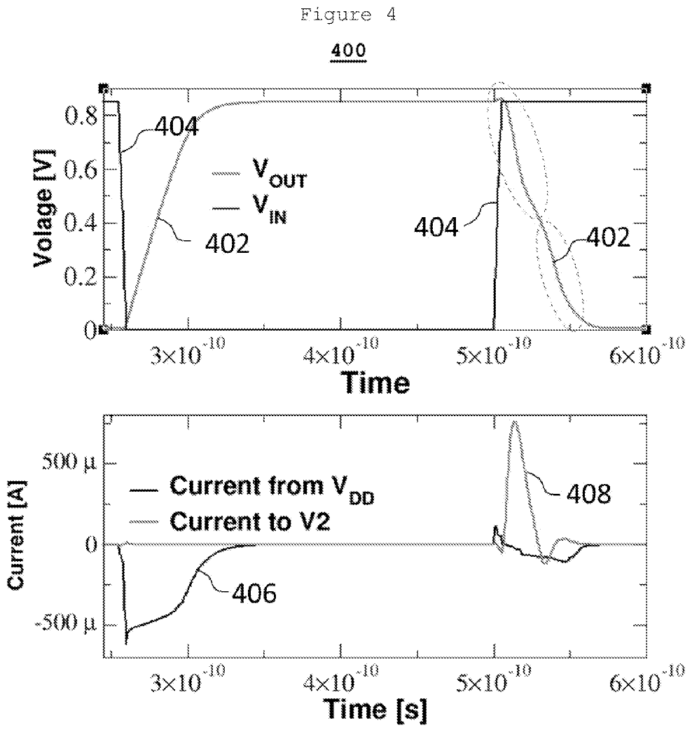

FIG. 4 400 is an illustration of the time dependent voltage waveforms of the output node OUT (310 in FIG. 3) shown as V_{OUT} 402 in FIG. 4. The input waveform driving the input 308 of the inverter in FIG. 3, V_{IN} 404 is also shown in FIG. 4

The waveform of current flow 406 into the inverter from the VDD power rail (324 in FIG. 3) is shown along the same x-axis (as used to plot voltage waveforms) in FIG. 4. The absolute value of the integral of this current 406 over time in FIG. 4 400 equals the total charge Q drained from the power rail (324 in FIG. 3) to drive the output from 0→1. Note that this charge is the same as drained by a conventional CMOS inverter shown in FIG. 2. The total charge transferred to the common grid/node V2 316 in FIG. 3 is the total area under the curve 408 in FIG. 4.

Note that the voltage waveform at the output node 310 in FIG. 3 is practically the same as the voltage waveform 202 of the output node (102 in schematic shown in FIG. 1) in FIG. 2 of a conventional inverter. In the schematic in FIG. 3 300 the total charge harvested from the output node 310 during a 140 transition to the common grid/node V2 316 is 25%-40% of the total charge drained from the power rail 324 in FIG. 3. Total current in the comparison is based on simulation of the entire circuit shown in FIG. 1 100 and FIG. 3 300—and thus includes parasitic contributions of all transistors to circuit operation. All parasitic capacitances of transistors and local wires in the complete schematic contribute to slew rate seen at the output and overheads incurred in propagation delay.

Switching energy consumption by logic gates with low fanouts (<4) are typically small. Gates driving a high fanout (>10) and/or long wires consume more energy and are best candidates for the proposed scheme that harvests charge from these large loads as they are discharged.

The transistor count increases in the proposed schematic shown in FIG. 3 300 compared to the 2 transistors used in a conventional CMOS inverter. However, the area consumed by the proposed schematics in FIG. 3 300 does not increase proportionally with the number of transistors because the transistors of gates (302, 304 in FIG. 3) are ˜5× smaller than any of the transistors (326, 314 and 320 in FIG. 3 300). This because the load seen by the NAND gate 302 is small—essentially just the gate input of a single PFET (P2 314 in FIG. 3)—with the load, from the delay element 304 much smaller. The transistors P1 320, N1 326 and P2 314 in FIG. 3 are comparable (in dimensions) to the transistors P1 114 and N1 116 in a conventional CMOS inverter shown in FIG. 1 100 that drives the same capacitive load C_{OUT} 104 in FIGS. 1 and 312 in FIG. 3. The gate footprint of the proposed schematic 300 (in FIG. 3) is not expected to be larger than 1.7×-2.0× of the CMOS inverter it replaces. Note that the proposed schematics are preferred as replacement candidates of CMOS inverters only when driving large loads—that offer the opportunity for larger energy reductions.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. An apparatus, comprising:
a power supply voltage terminal configured to provide a power supply voltage;
a reference ground voltage terminal;
an input terminal;
an output terminal;
a shared capacitor (1) operatively coupled to the output terminal and (2) configured to provide a capacitor voltage; and
a circuit switch associated with a delay, the circuit switch configured to, responsive to a low-to-high logic transition at the input terminal, sequentially (1) electrically couple then decouple the shared capacitor and the output terminal via a first pulse and (2) electrically couple then decouple the reference ground voltage terminal and the output terminal via a second pulse, the second pulse beginning after the first pulse begins and after the delay, the second pulse partially overlapping the first pulse.

2. The apparatus of claim 1, further comprising:
a NAND gate including a first input, a second input, and an output, the first input of the NAND gate being the input terminal and the second input of the NAND gate connected to the output terminal.

3. The apparatus of claim 1, further comprising:
a NAND gate including a first input, a second input, and an output, the first input of the NAND gate being the input terminal and the second input of the NAND gate connected to the output terminal; and
a first PFET including a gate terminal, a source terminal, and a drain terminal, the gate terminal of the first PFET connected to the input terminal, the source terminal of the first PFET connected to the power supply voltage terminal, the drain terminal of the first PFET connected to the output terminal.

4. The apparatus of claim 1, further comprising:
a NAND gate including a first input, a second input, and an output, the first input of the NAND gate being the input terminal and the second input of the NAND gate connected to the output terminal;
a first PFET including a gate terminal, a source terminal, and a drain terminal, the gate terminal of the first PFET connected to the input terminal, the source terminal of the first PFET connected to the power supply voltage terminal, the drain terminal of the first PFET connected to the output terminal; and
a second PFET including a gate terminal, a source, a terminal, and a drain terminal, the gate terminal of the second PFET connected to the output of the NAND gate, the source terminal of the second PFET connected to the output terminal, the drain terminal of the second PFET connected to the shared capacitor.

5. The apparatus of claim 1, wherein
a NAND gate including a first input, a second input, and an output, the first input of the NAND gate being the input terminal and the second input of the NAND gate connected to the output terminal;
a first PFET including a gate terminal, a source terminal, and a drain terminal, the gate terminal of the first PFET connected to the input terminal, the source terminal of the first PFET connected to the power supply voltage terminal, the drain terminal of the first PFET connected to the output terminal;
a second PFET including a gate terminal, a source, a terminal, and a drain terminal, the gate terminal of the second PFET connected to the output of the NAND gate, the source terminal of the second PFET connected to the output terminal, the drain terminal of the second PFET connected to the shared capacitor; and
following the low-to-high logic transition at the input terminal, a leading edge of an active-low pulse at the output of the NAND gate activates the second PFET during operation such that the power supply voltage terminal discharges harvested charge to the shared capacitor.

6. The apparatus of claim 1, further comprising:
a NAND gate including a first input, a second input, and an output, the first input of the NAND gate being the input terminal and the second input of the NAND gate connected to the output terminal;
a first PFET including a gate terminal, a source terminal, and a drain terminal, the gate terminal of the first PFET connected to the input terminal, the source terminal of the first PFET connected to the power supply voltage terminal, the drain terminal of the first PFET connected to the output terminal;
a second PFET including a gate terminal, a source, a terminal, and a drain terminal, the gate terminal of the second PFET connected to the output of the NAND gate, the source terminal of the second PFET connected to the output terminal, the drain terminal of the second PFET connected to the shared capacitor;
following the low-to-high logic transition at the input terminal, a leading edge of an active-low pulse at the output of the NAND gate activates the second PFET during operation such that the power supply voltage terminal discharges harvested charge to the shared capacitor; and
an NFET including a gate terminal, a source terminal, and a drain terminal, the source terminal of the NFET being connected to reference ground and the drain terminal of the NFET being connected to the output terminal.

7. The apparatus of claim 1, further comprising:
a NAND gate including a first input, a second input, and an output, the first input of the NAND gate being the input terminal and the second input of the NAND gate connected to the output terminal;
a first PFET including a gate terminal, a source terminal, and a drain terminal, the gate terminal of the first PFET connected to the input terminal, the source terminal of the first PFET connected to the power supply voltage terminal, the drain terminal of the first PFET connected to the output terminal;
a second PFET including a gate terminal, a source, a terminal, and a drain terminal, the gate terminal of the second PFET connected to the output of the NAND gate, the source terminal of the second PFET connected to the output terminal, the drain terminal of the second PFET connected to the shared capacitor;
following the low-to-high logic transition at the input terminal, a leading edge of an active-low pulse at the output of the NAND gate activates the second PFET during operation such that the power supply voltage terminal discharges harvested charge to the shared capacitor;
an NFET including a gate terminal, a source terminal, and a drain terminal, the source terminal of the NFET being connected to reference ground and the drain terminal of the NFET being connected to the output terminal; and
an inverter, an input of the inverter connected to the output of the NAND gate, an output of the inverter connected to the gate terminal of the NFET.

8. The apparatus of claim 7, wherein an active low pulse at the input of the inverter during operation causes the NFET to activate for a duration equal to a pulse duration of the active low pulse.

9. The apparatus of claim 7, wherein a propagation delay of the inverter during operation is substantially similar to a time for the output terminal to be discharged from the power supply voltage terminal to the capacitor voltage.

10. The apparatus of claim 7, wherein, during operation, a pulse width of an active low pulse at the output of the NAND gate is equal to a sum of a propagation delay of the inverter and a time for the NFET to discharge the output terminal to a logic threshold voltage of the NAND gate.

11. The apparatus of claim 10, wherein, during operation:
the low-to-high logic transition at the input terminal causes the active low pulse at the output of the NAND gate,
the active low pulse at the output of the NAND gate causes the second PFET to be activated, and
the active low pulse at the output of the NAND gate causes the inverter to activate the NFET.

12. The apparatus of claim 1, further comprising:
an NFET including a gate terminal, a source terminal, and a drain terminal, the gate terminal of the NFET connected to the input terminal, the source terminal of the NFET connected to reference ground, and the drain terminal connected to the output terminal.

13. An apparatus, comprising:
a power supply voltage terminal configured to provide a power supply voltage;
a node (1) operatively coupled to the power supply voltage terminal and (2) configured to provide a node voltage;
an input terminal operatively coupled to the power supply voltage and the node; and
an output terminal (1) operatively coupled to the power supply voltage, the node, and the input terminal and (2) configured to receive a high-to-low logic transition based on the power supply voltage and the node voltage following a low-to-high logic transition at the input terminal.

14. The apparatus of claim 13, further comprising:
a NAND gate including a first input, a second input, and an output, the first input of the NAND gate being the input terminal and the second input of the NAND gate connected to the output terminal;
a first PFET including a gate terminal, a source terminal, and a drain terminal, the gate terminal of the first PFET connected to the input terminal, the source terminal of the first PFET connected to the power supply voltage terminal, the drain terminal of the first PFET connected to the output terminal;
a second PFET including a gate terminal, a source, terminal, and a drain terminal, the gate terminal of the second PFET connected to the output of the NAND gate, the source terminal of the second PFET connected to the output terminal, the drain terminal of the second PFET connected to the node;
a first NFET including a gate terminal, a source terminal, and a drain terminal, the source terminal of the first NFET being connected to reference ground and the drain terminal of the first NFET being connected to the output terminal;
an inverter, an input of the inverter connected to the output of the NAND gate, an output of the inverter connected to the gate terminal of the first NFET; and
a second NFET including a gate terminal, a source terminal, and a drain terminal, the gate terminal of the second NFET connected to the input terminal, the source terminal of the second NFET connected to reference ground, and the drain terminal of the second NFET connected to the output terminal.

15. The apparatus of claim 14, wherein, during operation, following the low-to-high logic transition at the input terminal, a leading edge of an active-low pulse at the output of the NAND gate activates the second PFET such that the power supply voltage terminal discharges harvested charge to the node.

16. The apparatus of claim 14, wherein an active low pulse at the input of the inverter during operation causes the first NFET to activate for a duration equal to a pulse duration of the active low pulse.

17. The apparatus of claim 14, wherein a propagation delay of the inverter during operation is substantially similar to a time for the output terminal to be discharged from the power supply voltage terminal to the node voltage.

18. The apparatus of claim 14, wherein, during operation:
the low-to-high logic transition at the input terminal causes an active low pulse at the output of the NAND gate,
the active low pulse at the output of the NAND gate causes the second PFET to be activated, and
the active low pulse at the output of the NAND gate causes the inverter to activate the first NFET.

19. A method, comprising:
providing a power supply voltage at a power supply voltage terminal;
providing a node voltage at a node operatively coupled to the power supply voltage; and
receiving, at an output terminal, a high-to-low logic transition based on the power supply voltage and the node voltage following a low-to-high logic transition at an input terminal.

20. The method of claim 19, wherein the low-to-high logic transition is received at a NAND gate, the method further comprising:
in response to receiving the low-to-high logic transition, generating an output at the NAND gate that causes a first PFET to activate and discharge the node voltage to the output terminal; and
receiving, at an input of an inverter, the output of the NAND gate to cause an output of the inverter to activate an NFET, reference ground connected to the output terminal in response to activating the NFET.
